(19) United States
(12) Patent Application Publication
(10) Pub. No.: US 2008/0089120 A1
(43) Pub. Date: Apr. 17, 2008

(54) Resistive memory devices having a CMOS compatible electrolyte layer and methods of operating the same

(75) Inventors: Sang-jun Choi, Yongin-si (KR); Jung-hyun Lee, Yongin-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/896,215

(22) Filed: Aug. 30, 2007

(30) Foreign Application Priority Data
Oct. 16, 2006 (KR) 10-2006-0100386

(51) Int. Cl. H01L 47/00; G11C 11/00

(52) U.S. Cl. 365/163; 257/4; 257/E47.001

(57) ABSTRACT

Example embodiments may provide a resistive memory having an amorphous solid electrolyte layer and/or a method of operating the memory. The resistive memory may include a switching device and/or a storage node connected to the switching device. The storage node may include a lower electrode, an upper electrode crossing the lower electrode, and an amorphous solid electrolyte layer between the upper electrode and the lower electrode. The storage node may be useable as a data storage layer, wherein at least one of the upper electrode and the lower electrode may be formed of a diffusion metal.

### PRIORITY STATEMENT

This non-provisional patent application claims priority under 35 U.S.C. § 119 to Korean Patent Application No. 10-2006-0100386, filed on Oct. 16, 2006, in the Korean Intellectual Property Office, the disclosure of which is incorporated herein in its entirety by reference.

### BACKGROUND

1. Field

Example embodiments may relate to a nonvolatile memory, for example, to a resistive memory having an amorphous solid electrolyte layer and/or a method of operating the same.

2. Description of the Related Art

Related art semiconductor memory devices may include multiple memory cells that may be connected in circuitry. The dynamic random access memory (DRAM) may have one switch and/or one capacitor as one unit memory cell. The DRAM has may be capable of a higher integrity density and/or a higher operating speed. However, data stored in a DRAM may disappear if power is no longer supplied.

Related art nonvolatile memories may be capable of maintaining stored data if power is no longer supplied. Flash memory, which may be a type of nonvolatile memory, may have a nonvolatile characteristic, and may have lower integration density and/or slow operating speed compared to a DRAM.

Related art nonvolatile memories may include magnetic random access memory (MRAM), ferroelectric random access memory (FRAM), phase-change random access memory (PRAM), and/or resistance random access memory (RRAM).

A transition metal oxide may be used as a variable resistance layer of a related art RRAM.

A sulfide group material and/or a selenide group material may be useable as a data storage layer of a resistive memory. However, a sulfide group material and/or the selenide group material may be difficult to process using a CMOS process.

### SUMMARY

Example embodiments may provide a resistive memory using a solid electrolyte that may be readily processed by a CMOS process.

Example embodiments may provide a method of operating a resistive memory having an amorphous solid electrolyte layer that may be readily processed by a CMOS process.

Example embodiments may provide a switching device including a lower electrode, an upper electrode crossing the lower electrode, and/or an amorphous solid electrolyte layer that may be between the upper electrode and the lower electrode, wherein at least one of the upper electrode and the lower electrode may be formed of a diffusion metal.

The amorphous solid electrolyte layer may be formed of a telluride compound.

The amorphous solid electrolyte layer may be formed of GeTe, SbTe, GeSbTe, and/or another suitable material.

The diffusion metal may be formed of Cu, Ag, Zn, and/or another suitable material.

The amorphous solid electrolyte layer may be doped with N₂ or the like.

The amorphous solid electrolyte layer may have a thickness of about 3 to about 1000 nm.

The data storage layer may be a bipolar resistor.

Example embodiments may provide a method of operating a memory including an amorphous solid electrolyte layer by applying a voltage between the upper electrode and the lower electrode.

The applied voltage may be applying a writing voltage or a reading voltage.

The writing voltage may include a set voltage to an electrode formed of a diffusion metal and/or a reset voltage to an electrode formed of a diffusion metal.

The set voltage may make the data storage layer in a lower resistance state by applying a positive voltage higher than a threshold voltage to an electrode formed of a diffusion metal.

The reset voltage may make the data storage layer in a higher resistance state by applying a negative voltage higher than a threshold voltage to an electrode formed of a diffusion metal.

Resistance of the memory may be measured by applying a reading voltage and/or comparing the measured voltage to a reference resistance.

### BRIEF DESCRIPTION OF THE DRAWINGS

The above and/or other features and advantages of example embodiments will become more apparent by describing them in detail with reference to the attached drawings in which:

FIG. 1 is a cross-sectional view illustrating an example embodiment nonvolatile memory having an amorphous solid electrolyte;

FIG. 2 is a schematic drawing illustrating memory principles of example embodiments;

FIG. 3 is a graph showing a current vs. voltage characteristic of an example embodiment memory; and

FIG. 4 is a schematic perspective view illustrating an example embodiment switching device.

### DETAILED DESCRIPTION

It will be understood that when an element or layer is referred to as being “on”, “connected to” or “coupled to” another element or layer, it may be directly on, connected or coupled to the other element or layer or intervening elements or layers may be present. In contrast, when an element is referred to as being “directly on,” “directly connected to” or “directly coupled to” another element or layer, there may be no intervening elements or layers present. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Thus, a first element, component, region, layer or section discussed below could be termed a second element, component, region, layer or section without departing from the teachings of example embodiments

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting. As used herein, the singular forms “a”, “an” and “the” may be intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments may be described herein with reference to cross-section illustrations that may be schematic illustrations of idealized embodiments (and intermediate structures). As such, variations from the shapes of the illustrations as a result, for example, of manufacturing techniques and/or tolerances, are to be expected. Thus, the example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to limit the example embodiments.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

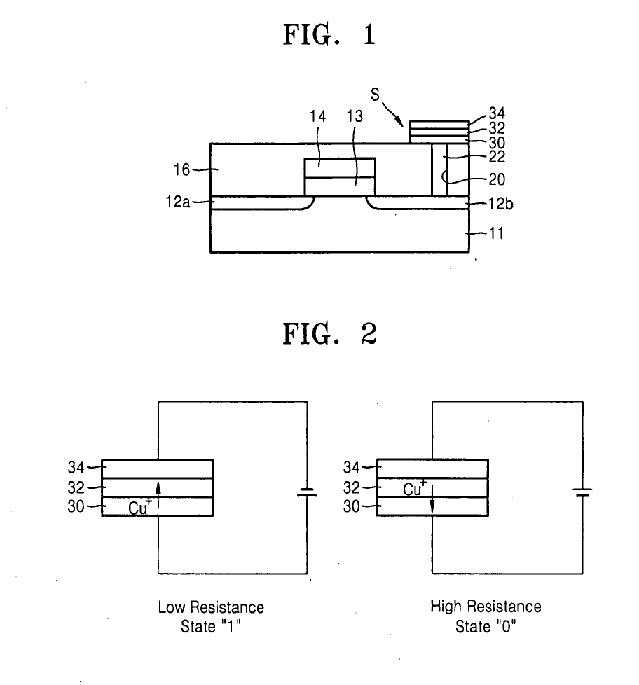

FIG. 1 is a cross-sectional view illustrating an example embodiment nonvolatile memory having an amorphous solid electrolyte.

As shown in FIG. 1, a gate oxide layer 13 and/or a gate electrode layer 14 may be on a substrate 11 that may include a first dopant region 12a and/or a second dopant region 12b. One of the first dopant region 12a and second dopant region 12b may be a source and/or the other one may be a drain. The gate electrode layer 14, the first dopant region 12a, and/or the second dopant region 12b may form a transistor. An interlayer insulating layer 16 covering the transistor may be on the substrate 11. A contact hole 20 may expose the second dopant region 12b through the interlayer insulating layer 16, and/or the contact hole 20 may be filled with a conductive plug 22. A storage node S covering an exposed portion of the conductive plug 22 may be on the interlayer insulating layer 16.

The storage node S may include a lower electrode 30, an amorphous solid electrolyte layer 32, and/or an upper electrode 34. FIG. 1 illustrates a cross-sectional view of a 1T(transistor)-1R(resistor) structure in which a resistive memory that may use the amorphous solid electrolyte layer 32 as a data storage layer may be connected to a transistor that may act as switch.

A 1 D (diode)-1R (resistor) structure may have resistive memory connected to a diode structure that may include a p-type semiconductor layer and/or an n-type semiconductor layer instead of a transistor structure.

The resistance state of the amorphous solid electrolyte layer 32 may vary according to types of voltage applied. The amorphous solid electrolyte layer 32 may be formed of a telluride compound, for example, GeTe, SbTe, GeSbTe, and/or another suitable material. The amorphous solid electrolyte layer 32 may have a higher resistance value, for example, of a few mega-ohm (MΩ), in an amorphous state.

One of the lower electrode 30 and the upper electrode 34 may be a diffusion metal that may diffuse metal ions into the amorphous solid electrolyte layer 32. The diffusion metal may be, for example, Cu, Ag, Zn, and/or another suitable material.

If one of the lower electrode 30 and/or the upper electrode 34 is formed of a diffusion metal, the other electrode may be formed one of a conductive nitride, for example, TaN, TiN, and any other suitable material, and a metal, for example, Pt, Ru, Ir, Au, Ag, Ti, and/or any other suitable material generally used for forming an electrode.

The amorphous solid electrolyte layer 32 may be deposited at a lower temperature and/or N₂ may be doped in the deposition process. The N₂ doping may facilitate the amorphousness of the solid electrolyte layer 32. The amorphous solid electrolyte layer 32 may be formed at a thickness of about 3 nm if an atomic layer deposition method is used and/or may be formed at a thickness of about 1 μm if a physical vapor deposition (PVD) and/or chemical vapor deposition (CVD) method is used. If the amorphous solid electrolyte layer 32 may be usable as a data storage layer if the layer has a thickness less than about 1 μm.

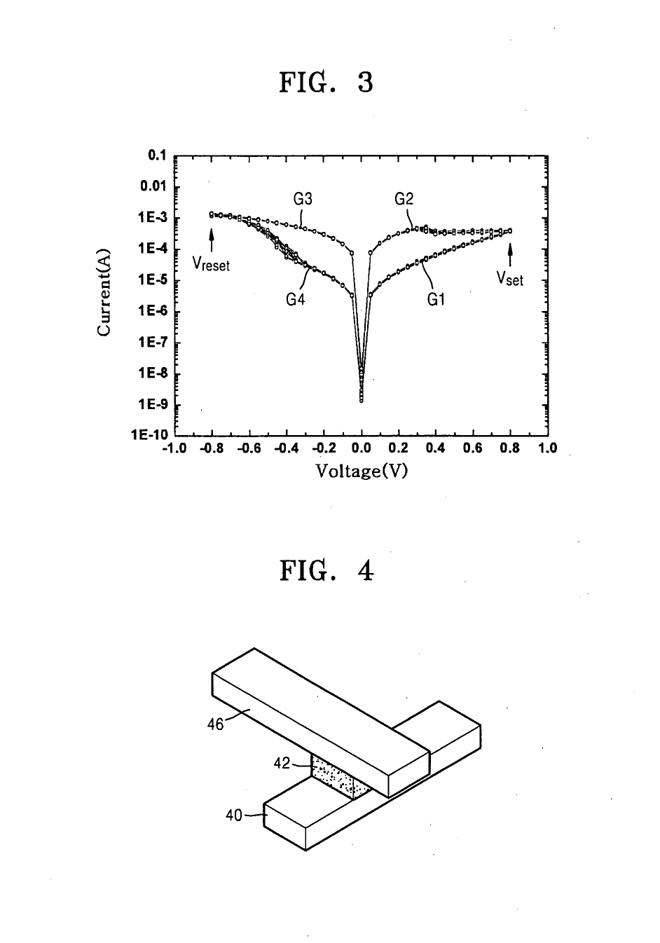

FIG. 2 is a schematic drawing illustrating principles of an example embodiment memory, and FIG. 3 is a graph showing current vs. voltage characteristic of an example embodiment memory.

As shown in FIG. 2, a storage node may include the lower electrode 30, the amorphous solid electrolyte layer 32 as a data storage layer, and/or the upper electrode 34. The lower electrode 30 may be formed of, for example, Cu, as a metal diffusion layer, and/or the upper electrode 34 may be formed of, for example, TaN, which may be generally used for forming an ordinary electrode. The amorphous solid electrolyte layer 32 may be formed of, for example, GeTe, to a thickness of about 100 nm, and/or N₂ may be doped in the amorphous solid electrolyte layer 32 in a process of depositing amorphous GeTe.

A voltage source may be connected between the lower electrode 30 and the upper electrode 34. The voltage source may be a direct current voltage source and/or the direction of the current flow may be changeable.

If a positive voltage is applied to the lower electrode 30 and a negative voltage is applied to the upper electrode 34, a current path may be generated in the amorphous solid electrolyte layer 32 due to the migration of Cu⁺ ions into the amorphous solid electrolyte layer 32 from the lower electrode 30. As a result, the amorphous solid electrolyte layer 32 may be in a lower resistance state. If a negative voltage is applied to the lower electrode 30 and a positive voltage is applied to the upper electrode 34, current may be reduced or eliminated due to the migration of Cu⁺ ions into the lower electrode 30 from the amorphous solid electrolyte layer 32. As a result, the amorphous solid electrolyte layer 32 may be in a higher resistance state. If the lower resistance state is defined as “1” and/or the higher resistance state is defined as “0”, two bit information data may be stored in the amorphous solid electrolyte layer 32.

An example embodiment method of operating a memory is described in FIG. 3.

As shown in FIG. 3, in the current-voltage characteristics of an example embodiment memory, switching characteristics are shown in both a positive voltage region and a negative voltage region. A data storage layer of an example embodiment memory may be a bipolar resistor having a switching characteristic in positive and negative voltage regions.

In FIG. 3, a first graph G1 indicates that the amorphous solid electrolyte layer 32 may have a large resistance and a lower current. If an increased positive voltage is applied to the lower electrode 30, at a voltage equal to or greater than a set threshold voltage Vset, Cu⁺ ions may migrate into the amorphous solid electrolyte layer 32 from the lower electrode 30 and/or a current path may be generated in the amorphous solid electrolyte layer 32. The resistance of the amorphous solid electrolyte layer 32 may decrease and current may increase. The voltage-current characteristic of the memory may follow a second graph G2 in a lower resistance state.

If a threshold voltage, for example, less than an absolute value reset voltage is applied to the lower electrode 30, the resistance of the amorphous solid electrolyte layer 32 may be maintained in a lower state, and/or the current-voltage characteristic of the memory may follow a third graph G3. If a reset voltage Vreset is applied to the lower electrode 30, the amorphous solid electrolyte layer 32 may return to a higher resistance state if Cu⁺ ions migrate into the lower electrode 30 from the amorphous solid electrolyte layer 32, and the current-voltage characteristic may follow a fourth graph G4. G2 and/or G3 graphs may show lower resistance states, and G1 and/or G4 show higher resistance state.

As shown in FIG. 3, example embodiment memory may have an operating voltage of less than about 1 μA unit, and/or a lower operating voltage may enable size reduction of the transistor of the memory and/or may be applied in a higher integration density memory.

The amorphous solid electrolyte layer 32 may use a telluride compound, and the telluride compound may be processed by an etching process of a CMOS process.

As shown in FIG. 3, an example embodiment memory that includes an amorphous solid electrolyte layer may have switching characteristics.

An example embodiment method of operating a memory will now be described with reference to FIGS. 1 through 3.

Writing

A writing voltage may be applied to the lower electrode 30 and/or the upper electrode 34. The writing voltage may be a set voltage Vset applied to a diffusion electrode (lower electrode 30 in FIG. 2) so that the switching characteristic of the second graph G2 in FIG. 3 may be achieved. If the memory adopts the characteristic of the second graph G2, the memory may be in a lower resistance state and data “1” may be recorded.

A negative voltage, which may be a reset voltage Vreset, may be applied to the diffusion electrode (lower electrode 30 in FIG. 2) so that the memory may be in a higher resistance state. The current-voltage characteristic of the memory may resemble the fourth graph G4. The memory may be in a higher resistance state, and data “0” may be recorded.

Reading

Resistance of an example embodiment memory may be measured by applying a reading voltage between the upper electrode 34 and the lower electrode 30. The reading voltage may apply a positive voltage lower than the set voltage Vset and/or a negative voltage lower than an absolute value of a reset voltage Vreset to the diffusion electrode.

If the measured current resembles the second graph G2 and/or the third graph G3 with respect to the reading voltage applied between the upper electrode 34 and the lower electrode 30, the resistance of the memory may be a first resistance. If the measured current resembles the first graph G1 and/or the fourth graph G4 with respect to the voltage applied, the resistance of the memory may be a second resistance.

The measured resistance may be compared with a reference resistance having a value between the first and second resistances. The first resistance may be smaller than the reference resistance. If the first resistance is measured by applying the reading voltage, it may be data “1.” The second resistance may be larger than the reference resistance. If the second resistance is measured by applying the reading voltage, it may be data “0.”

In FIGS. 1 through 3, the amorphous solid electrolyte layer 32 may be used as a data storage layer in an example embodiment memory. The storage node structure that includes the amorphous solid electrolyte layer 32 may also be used as a switching device.

FIG. 4 is a schematic perspective view illustrating an example embodiment switching. Like reference numerals may be used to indicate elements that are substantially identical to the elements of FIG. 1, and redundant descriptions may not be repeated.

As shown in FIG. 4, an example embodiment switching device may include a lower electrode 40, an amorphous solid electrolyte layer 42 on the lower electrode 40, and/or an upper electrode 46 formed on the amorphous solid electrolyte layer 42. The lower electrode 40 and/or the upper electrode 46 may be formed in a line shape. The lower electrode 40 and/or the upper electrode 46 may cross each other. The lower electrode 40 and/or the upper electrode 46 may be formed in multiple parallel lines, and/or the amorphous solid electrolyte layer 42 may be formed in an area where the plurality of lower electrodes 40 and the plurality of upper electrodes 46 cross each other. the example embodiment switching device may form an array.

One of the lower electrode 40 and the upper electrode 46 may be a diffusion layer.

The amorphous solid electrolyte layer 42 may be in a higher resistance state or a lower resistance state depending on a voltage applied to an electrode formed of a diffusion metal. It may be possible for current to flow or be blocked in an addressed amorphous solid electrolyte layer 42. The example embodiment switching device may act as a switch.

The storage node structure of an example embodiment memory described with reference to FIGS. 1 through 3 can be used as a switching device. The example embodiment structure and operation of the switching device may be seen from the memory described above.

In an example embodiment memory, a storage node may be formed using an amorphous solid electrolyte layer and/or a diffusion metal layer and/or may be formed using a compatible process with a CMOS process. Example embodiment memory may have a lower operation current and may be used in a higher integration density memory.

While example embodiments have been particularly shown and described with reference to exemplary embodiments thereof, it will be understood by those of ordinary skill in the art that various changes in form and details may be made therein without departing from the spirit and scope of the following claims.

What is claimed is:

1. A switching device comprising:
a lower electrode;
an upper electrode; and
an amorphous solid electrolyte layer between the upper electrode and the lower electrode, the amorphous solid electrolyte layer being compatible with a CMOS process, wherein at least one of the upper electrode and the lower electrode is formed of a diffusion metal.

2. The switching device of claim 1, wherein the amorphous solid electrolyte layer is formed of a telluride compound.

3. The switching device of claim 2, wherein the amorphous solid electrolyte layer is formed of at least one material selected from the group consisting of GeTe, SbTe, and GeSbTe.

4. The switching device of claim 1, wherein the diffusion metal is at least one material selected from the group consisting of Cu, Ag, and Zn.

5. The switching device of claim 1, wherein the amorphous solid electrolyte layer is doped with N₂.

6. The switching device of claim 1, wherein the amorphous solid electrolyte layer has a thickness of about 3 to about 1000 nm.

7. A memory device comprising:
a switching device; and
a storage node connected to the switching device, wherein the storage node includes a lower electrode, an upper electrode, and an amorphous solid electrolyte layer between the upper electrode and the lower electrode, the amorphous solid electrolyte layer configured to be useable as a data storage layer, wherein at least one of the upper electrode and the lower electrode is formed of a diffusion metal.

8. The memory device of claim 7, wherein the amorphous solid electrolyte layer is formed of a telluride compound.

9. The memory device of claim 8, wherein the amorphous solid electrolyte layer is formed of at least one material selected from the group consisting of GeTe, SbTe, and GeSbTe.

10. The memory device of claim 7, wherein the diffusion metal is at least one material selected from the group consisting of Cu, Ag, and Zn.

11. The memory device of claim 7, wherein the amorphous solid electrolyte layer is doped with N₂.

12. The memory device of claim 7, wherein the data storage layer is a bipolar resistor.

13. The memory device of claim 7, wherein the data storage layer has a thickness of about 3 to about 1000 nm.

14. A method of operating a memory device having a switching device and a storage node connected to the switching device, the storage node including a lower electrode, an upper electrode, and a CMOS-compatible amorphous solid electrolyte layer between the upper electrode and the lower electrode comprising:
applying a voltage between the upper electrode and the lower electrode.

15. The method of claim 14, wherein the applying a voltage includes applying one of a writing voltage and a reading voltage.

16. The method of claim 15, wherein the applying a writing voltage includes applying a set voltage to at least one of the upper and the lower and applying a reset voltage to at least one of the upper and the lower electrode.

17. The method of claim 16, wherein the applying a set voltage includes setting the amorphous solid electrolyte layer in a set resistance state by applying a positive voltage to the at least one of the upper and the lower electrode, wherein the positive voltage is higher than a threshold voltage.

18. The method of claim 16, wherein the applying a reset voltage includes setting the amorphous solid electrolyte layer in a reset resistance state by applying a negative voltage to the at least one of the upper and the lower electrode, wherein the negative voltage has an absolute value higher than a threshold voltage.

19. The method of claim 15, wherein the applying a reading voltage includes measuring a resistance of the memory device by applying the reading voltage and comparing the measured resistance to a reference resistance.
